(19) United States
(12) Patent Application Publication
(10) Pub. No.: US 2006/0176678 A1
(43) Pub. Date: Aug. 10, 2006

(54) Front side bus module

(75) Inventors: Wen-Yen Lin, Taoyuan City (TW); Tsan-Nan Chien, Taipei City (TW); Yu Liu, Taipei City (TW); Chih-Ming Liu, Taipei Shien (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Quanta Computer Inc.

(21) Appl. No.: 11/375,951

(22) Filed: Mar. 15, 2006

Related U.S. Application Data
(62) Division of application No. 10/818,256, filed on Apr. 5, 2004.

(30) Foreign Application Priority Data
Apr. 11, 2003 (TW) 92108360

(51) Int. Cl. H05K 9/00

(52) U.S. Cl. 361/818; 361/783

(57) ABSTRACT

A front side bus module is disclosed. The front side bus module includes a high density interconnection substrate and a plurality of high speed devices, wherein the high speed devices are disposed on the high density interconnection substrate and electrically connected therethrough.

### BACKGROUND OF THE INVENTION

1. Field of the Invention

The present invention relates to a computer function module and in particular to a front side bus module of a computer.

2. Description of the Related Art

Recently, the speed of the front side bus (FSB) in a computer system has been increased from 333 MHz, 400 MHz, and 500 MHz to 800 MHz progressively and all systems equipped with front side bus are typically disposed on a motherboard. With increased front side bus speeds, heat dissipation, signal quality, and electromagnetic interference are significant concerns. However, modifying the front side bus accordingly affects layout of other systems on the motherboard. In addition, some industrial standard variations, for example input/output, storage, power supply module, and others also affect the layout of the front side bus. Because of the reciprocal effects described, design and fabrication of motherboards increases both time and cost of fabrication.

Moreover, single chips provide more functions with precision semiconductor technology, especially devices on the front side bus. Thus, pin counts also increase and high density interconnection (HDI) substrates are more often used for motherboard substrate fabrication. Although the HDI substrate provides high density connecting lines and better signal transmission, HDI substrate costs are many times higher than those for typical print circuit boards. Furthermore, not all devices or systems on the motherboard are high speed and/or high density, and thus do not require connection through the HDI substrate. For the reasons described, replacing the typical print circuit board with the HDI substrate is not economical.

### SUMMARY OF THE INVENTION

Accordingly, an object of the invention is to provide a front side bus module to integrate high speed devices and solve heat dissipation, signal quality, and electromagnetic interference problems simultaneously.

The present invention provides a front side bus module. The front side bus module includes a high density interconnection (HDI) substrate and a plurality of high speed devices, disposed on the high density interconnection substrate and electrically connected with each other therethrough.

The present invention also provides a motherboard including a main circuit board, and a high density interconnection (HDI) substrate, wherein the main circuit board and the HDI substrate are electrically connected. Some high speed devices such as the North Bridge, the random access memory (RAM), and the central processing unit (CPU), are disposed on the HDI substrate and are electrically connected with each other therethrough. Finally, an electromagnetic inference (EMI) shield covers the HDI substrate.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 shows a block diagram of a computer system;

FIG. 2 shows the front side bus module of the present invention.

### DETAILED DESCRIPTION OF THE INVENTION

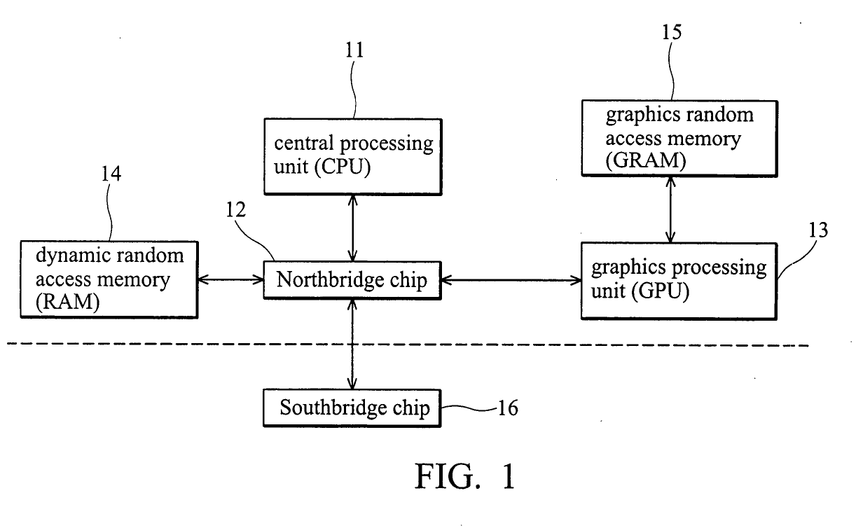

FIG. 1 shows a block diagram of a computer system. The architecture of the computer system includes a central processing unit (CPU) 11, a North Bridge chip 12, a graphics processing unit (GPU) 13 (or accelerated graphics port AGP), a dynamic random access memory (DRAM) 14, a graphics random access memory (GRAM) 15, and a South Bridge chip 16 as shown in FIG. 1.

A data transmission interface between the North Bridge chip 12 and the South Bridge chip 16 is an interface with a low transmission speed which is lower than the speed that the CPU communicated with the system memory. The high speed devices including the CPU 11, the North Bridge chip 12, the graphics processing unit (GPU) 14 (or accelerated graphics port, AGP), the dynamic random access memory (DRAM) 14, and the graphics random access memory (GRAM) 15 shown in the FIG. 1, which transmit data with the speed that the CPU communicated with the system memory. And data transmission interfaces among the high speed devices in the front side bus are the interfaces with a high transmission speed as the CPU communicated with the system memory.

Basically, according to the data transmission speed, the high speed devices including the CPU 11, the North Bridge chip 12, the graphics processing unit (GPU) 14 (or accelerated graphics port, AGP), the dynamic random access memory (DRAM) 14, and the graphics random access memory (GRAM) 15 above the dotted line in FIG. 1, can be treated as an individual sub-system.

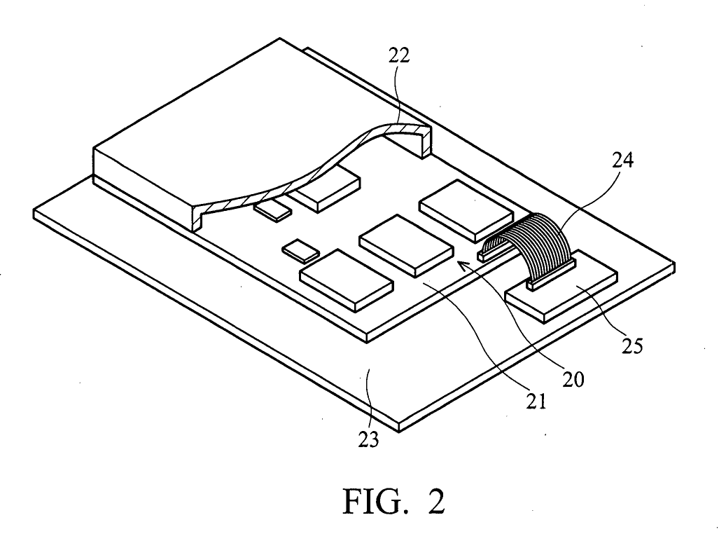

In the present embodiment, the high speed devices such as the CPU, North Bridge chip, GPU, AGP, DRAM and GRAM are integrated on a high density interconnection (HDI) substrate 21 to form a front side bus (FSB) module 20, as shown in FIG. 2. Peripheral devices like input/output, storage circuit and others (not shown in FIG. 2) are disposed on the main circuit board 23 that can be made from a typical print circuit board. The front side bus module 20 is electrically connected to the main circuit board 23 by a bus line 25, connector, or solder to construct a complete computer system.

The speed of the front side bus is one of the key factors in the evolution of computer platform. In the present invention, the high speed devices are integrated to form the front side bus module which can be individually replaced during system upgrade, and thus other low speed devices connected to the South Bridge chip on the motherboard need not be changed. Because the low speed devices connected to the South Bridge chip are not critical equipment to be replaced during upgrade, all except the high speed devices on the front side bus module can be retained on the motherboard to reduce cost.

In addition, since the high speed devices which generate electromagnetic radiation are integrated in the front side bus module 20, there is a need to provide the front side bus module 20 with protection from electromagnetic interference. Hence, an electromagnetic interference (EMI) shield 22 is provided to cover the front side bus module 20, shielding off the electromagnetic radiation generated by the devices in the front side bus module 20 such that the electromagnetic radiation cannot influence other devices on the motherboard. Furthermore, the (EMI) shield 22 also protects the high speed devices in the front side bus module from external electromagnetic interference. The (EMI) shield 22 can be made of conductive material such as aluminum or copper.

Because the high speed devices causing problems of heat dissipation are concentrated in the front side bus module 20, heat pipes, micro fins, vapor chambers, water cooling devices, and other efficient heat dissipating devices can be used to easily solve the heat dissipation problem of the front side bus module 20. In contrast, the conventional motherboard has to dissipate heat respectively, because the heat-generating high speed devices are apart from each other and not concentrated in a same area on the motherboard.

The link between the power supply module 24 and the front side bus module 20 must be metal or conductor of considerable thickness such that the impedance of the link can be reduced to stabilize transmission quality and the link can also receive required electric currents. Furthermore, the power supply module 24 can be disposed on the main circuit board 23, as shown in FIG. 2, or disposed on the HDI substrate 21, not shown in FIG. 2, wherein the link between the power supply module 24 and the front side bus module 20 can be bus line 25, solder, or connector. When the power supply module 24 is disposed on the HDI substrate 24, the power supply module 24 can be disposed on one side of the HDI substrate 24 where the front side bus module 20 is disposed on the other. Furthermore, the power supply module 24 and the front side bus module 20 can be disposed on the same side of the HDI substrate 24.

While the invention has been described by way of example and in terms of the preferred embodiment, it is to be understood that the invention is not limited to the disclosed embodiment. To the contrary, it is intended to cover various modifications and similar arrangements (as would be apparent to those skilled in the art). Therefore, the scope of the appended claims should be accorded the broadest interpretation so as to encompass all such modifications and similar arrangements.

1.-7. (canceled)

8. A motherboard, comprising:
a main circuit board;
a front side bus module electrically connected to the main circuit board; and
an electromagnetic interference (EMI) shield covering the front side bus module.

9. The motherboard as claimed in claim 8, wherein the front side bus module comprises:
a high density interconnection (HDI) substrate; and
a plurality of high speed devices disposed on the high density interconnection substrate and electrically connected.

10. The motherboard as claimed in claim 9, wherein the high speed devices comprise:
a North Bridge chip disposed on the high density interconnection substrate;
a central processing unit (CPU) disposed on the high density interconnection substrate and electrically connected to the North Bridge chip; and
a random-access memory (RAM) disposed on the high density interconnection substrate and electrically connected to the North Bridge chip.

11. The motherboard as claimed in claim 10, wherein the high speed devices further comprise a graphics processing unit (GPU) disposed on the high density interconnection substrate and electrically connected to the North Bridge chip.

12. The motherboard as claimed in claim 10, wherein the high speed devices further comprise an accelerated graphics port (AGP) disposed on the high density interconnection substrate and electrically connected to the North Bridge chip.

13. The motherboard as claimed in claim 9, further comprising a connector to connect the front side bus module and the main circuit board for signal transmission.

14. The motherboard as claimed in claim 9, further comprising a bus line to connect the front side bus module and the main circuit board for signal transmission.

15. The motherboard as claimed in claim 9, wherein the front side bus module is connected to the main circuit board by solder.

16. The motherboard as claimed in claim 9, wherein the electromagnetic interference (EMI) shield is made of conductive material.

17. The motherboard as claimed in claim 9, further comprising a power supply module disposed on the main circuit board and electrically connected to the front side bus module.

18. The motherboard as claimed in claim 17, wherein the front side bus module is connected to the power supply module by solder.

19. The motherboard as claimed in claim 17, further comprising a bus line to electrically connect the front side bus module and the power supply module.

20. The motherboard as claimed in claim 17, further comprising a connector to electrically connect the front side bus module and the power supply module.

21. The motherboard as claimed in claim 9, further comprising a power supply module disposed on the high density interconnection substrate and electrically connected to the high speed devices.
